(19) United States
(12) Patent Application Publication
(10) Pub. No.: US 2009/0194026 A1
(43) Pub. Date: Aug. 6, 2009

(54) PROCESSING SYSTEM FOR FABRICATING COMPOUND NITRIDE SEMICONDUCTOR DEVICES

(76) Inventors: BRIAN H. BURROWS, San Jose, CA (US); Lori D. Washington, Union City, CA (US); Ronald Stevens, San Ramon, CA (US); Kenric T. Choi, San Jose, CA (US); Anthony F. White, Cupertino, CA (US); Roger N. Anderson, Sunnyvale, CA (US); Sandeep Nijhawan, Los Altos, CA (US); Joshua J. Podesta, San Jose, CA (US); Alexander Tam, Union City, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/023,572

(22) Filed: Jan. 31, 2008

(51) Int. Cl. C23C 16/54

(52) U.S. Cl. 118/719; 118/729

(57) ABSTRACT

One embodiment of a processing system for fabricating compound nitride semiconductor devices comprises one or more processing chamber operable with form a compound nitride semiconductor layer on a substrate, a transfer chamber coupled with the processing chamber, a loadlock chamber coupled with the transfer chamber, and a load station coupled with the loadlock chamber, wherein the load station comprises a conveyor tray movable to convey a carrier plate loaded with one or more substrates into the loadlock chamber. Compared to a single chamber reactor, the multi-chamber processing system expands the potential complexity and variety of compound structures. Additionally, the system can achieve higher quality and yield by specialization of individual chambers for specific epitaxial growth processes. Throughput is increased by simultaneous processing in multiple chambers.

### BACKGROUND OF THE INVENTION

1. Field of the Invention

Embodiments of the present invention generally relate to the manufacture of compound nitride semiconductor devices, such as light emitting diodes (LEDs), and, more particularly, to a processing system integrating one or more processing chambers that implement hydride vapor phase epitaxial (HVPE) deposition and/or metal-organic chemical vapor deposition (MOCVD) techniques to fabricate such devices.

2. Description of the Related Art

The history of light-emitting diodes (“LEDs”) is sometimes characterized as a “crawl up the spectrum.” This is because the first commercial LEDs produced light in the infrared portion of the spectrum, followed by the development of red LEDs that used GaAsP on a GaAs substrate. This was, in turn, followed by the use of GaP LEDs with improved efficiency that permitted the production of both brighter red LEDs and orange LEDs. Refinements in the use of GaP then permitted the development of green LEDs, with dual GaP chips (one in red and one in green) permitting the generation of yellow light. Further improvements in efficiency in this portion of the spectrum were later enabled through the use of GaAlAsP and InGaAlP materials.

This evolution towards the production of LEDs that provide light at progressively shorter wavelengths has generally been desirable not only for its ability to provide broad spectral coverage but because diode production of short-wavelength light may improve the information storage capacity of optical devices like CD-ROMs. The production of LEDs in the blue, violet, and ultraviolet portions of the spectrum was largely enabled by the development of nitride-based LEDs, particularly through the use of GaN. While some modestly successful efforts had previously been made in the production of blue LEDs using SiC materials, such devices suffered from poor luminescence as a consequence of the fact that their electronic structure has an indirect bandgap.

While the feasibility of using GaN to create photoluminescence in the blue region of the spectrum has been known for decades, there were numerous barriers that impeded their practical fabrication. These barriers included the lack of a suitable substrate on which to grow the GaN structures, generally high thermal requirements for growing GaN that resulted in various thermal-convection problems and a variety of difficulties in efficient p-doping of such materials. The use of sapphire as a substrate was not completely satisfactory because it provides approximately a 15% lattice mismatch with the GaN. Progress has subsequently been made in addressing many aspects of these barriers. For example, the use of a buffer layer of AlN or GaN formed from a metal-organic vapor has been found effective in accommodating the lattice mismatch. Further refinements in the production of Ga—N-based structures has included the use of AlGaN materials to form heterojunctions with GaN and particularly the use of InGaN, which causes the creation of defects that act as quantum wells to emit light efficiently at short wavelengths. Indium-rich regions have a smaller bandgap than surrounding material, and may be distributed throughout the material to provide efficient emission centers.

While some improvements have thus been made in the manufacture of such compound nitride semiconductor devices, it is widely recognized that a number of deficiencies yet exist in current manufacturing processes. Moreover, the high utility of devices that generate light at such wavelengths has caused the production of such devices to be an area of intense interest and activity. In view of these considerations, there is a general need in the art for improved methods and systems for fabricating compound nitride semiconductor devices.

### SUMMARY OF THE INVENTION

The present invention generally provides an integrated processing system for manufacturing compound nitride semiconductor devices. The processing system comprises one or more walls that form a transfer region that has a robot disposed therein, one or more processing chambers operable to form one or more compound nitride semiconductor layers on a substrate that are in transferable communication with the transfer region, a loadlock chamber in transferable communication with the transfer region, the loadlock chamber having an inlet and an outlet valve to receive at least one substrate into a vacuum environment, and a load station in communication with the loadlock chamber, wherein the load station comprises a conveyor tray movable to convey a carrier plate loaded with one or more substrates into the loadlock chamber.

Embodiments of the invention further provide an integrated processing system for manufacturing compound nitride semiconductor devices. The processing system comprises one or more walls that form a transfer region that has a robot disposed therein and a first processing chamber that is in communication with the transfer region. The first processing chamber comprises a substrate support positioned within a processing volume of the first processing chamber, a showerhead defining a top portion of the processing region, and a plurality of lamps forming one or more zones located below the processing region and adapted to direct radiant heat toward the substrate support creating one or more radiant heat zones. The integrated processing system further comprises a loadlock chamber in transferable with the transfer region and a load station in communication with the loadlock chamber, wherein the load station comprises a conveyor tray movable to convey a carrier plate loaded with one or more substrates into the loadlock chamber.

Embodiments of the invention further provide an integrated processing system for manufacturing compound nitride semiconductor devices. The integrated processing system comprises one or more walls that form a transfer region that has a robot disposed therein, one or more metalorganic chemical vapor deposition (MOCVD) chambers operable to form a compound nitride semiconductor layer on a substrate in transferable communication with the transfer region, and one or more hydride vapor phase epitaxy (HVPE) chambers operable to form a compound nitride semiconductor layer on a substrate in transferable communication with the transfer region.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is an isometric view illustrating a processing system according to an embodiment of the invention;

FIG. 2 is a plan view of the processing system illustrated in FIG. 1;

FIG. 3 is an isometric view illustrating a load station and loadlock chamber according to an embodiment of the invention;

FIG. 4 is a schematic view of a loadlock chamber according to an embodiment of the invention;

FIG. 5 is an isometric view of a carrier plate according to an embodiment of the invention;

FIG. 6 is a schematic view of a batch loadlock chamber according to an embodiment of the invention;

FIG. 7 is an isometric view of a work platform according to an embodiment of the invention;

FIG. 8 is a plan view of a transfer chamber according to an embodiment of the invention;

FIG. 9 is a schematic cross-sectional view of a HVPE chamber according to an embodiment of the invention;

FIG. 10 is a schematic cross-sectional view of an MOCVD chamber according to an embodiment of the invention;

FIG. 11 is a schematic view illustrating another embodiment of a processing system for fabricating compound nitride semiconductor devices; and

FIG. 12 is a schematic view illustrating yet another embodiment of a processing system for fabricating compound nitride semiconductor devices.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally provides an apparatus and method for simultaneously processing substrates using a multi-chamber processing system (e.g. a cluster tool) that has an increased system throughput, increased system reliability, and increased substrate to substrate uniformity. In one embodiment, the processing system is adapted to fabricate compound nitride semiconductor devices in which a substrate is disposed in a HVPE chamber where a first layer is deposited on the substrate and then the substrate is transferred to a MOCVD chamber where a second layer is deposited over the first layer. In one embodiment, the first layer is deposited over the substrate with a thermal chemical-vapor-deposition process using a first group-III element and a nitrogen precursor and the second layer is deposited over the first layer with a thermal chemical-vapor deposition process using a second group-III precursor and a second nitrogen precursor. Although described in connection to a processing system that comprises one MOCVD chamber and one HVPE chamber, alternate embodiments may integrate one or more MOCVD and HVPE chambers. Exemplary systems and chambers that may be adapted to practice the present invention are described in U.S. patent application Ser. No. 11/404,516, filed on Apr. 14, 2006, titled EPITAXIAL GROWTH OF COMPOUND NITRIDE SEMICONDUCTOR STRUCTURES and U.S. patent application Ser. No. 11/429,022, filed on May 5, 2006, titled PARASITIC PARTICLE SUPPRESSION IN GROWTH OF III-V NITRIDE FILMS USING MOCVD AND HVPE, both of which are incorporated by reference in their entireties.

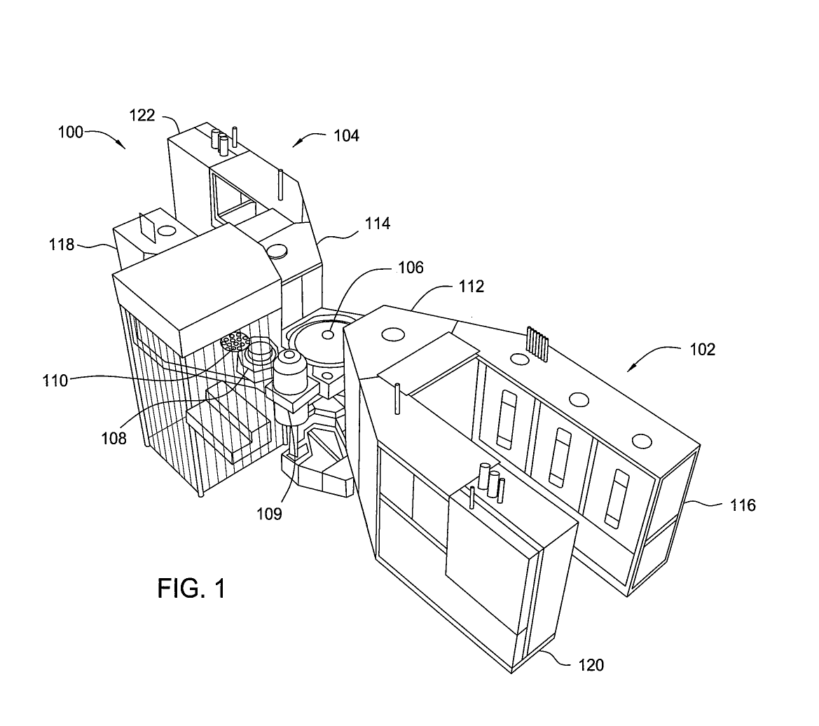

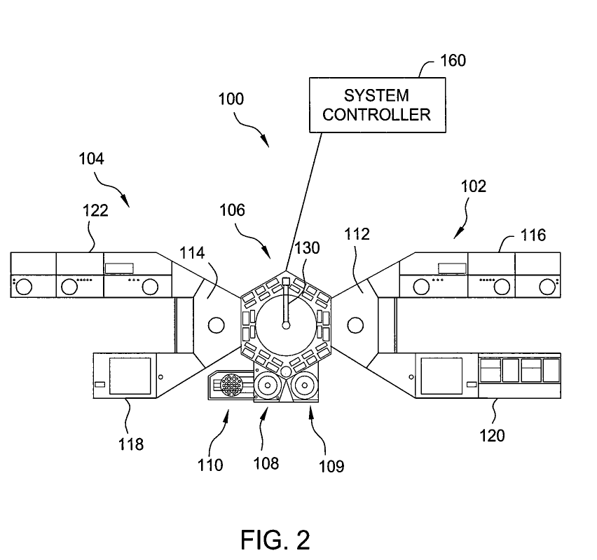

FIG. 1 is an isometric view of one embodiment of a processing system 100 that illustrates a number of aspects of the present invention that may be used to advantage. FIG. 2 illustrates a plan view of one embodiment of a processing system 100 illustrated in FIG. 1. With reference to FIG. 1 and FIG. 2, the processing system 100 comprises a transfer chamber 106 housing a substrate handler, a plurality of processing chambers coupled with the transfer chamber, such as a MOCVD chamber 102 and a HVPE chamber 104, a loadlock chamber 108 coupled with the transfer chamber 106, a batch loadlock chamber 109, for storing substrates, coupled with the transfer chamber 106, and a load station 110, for loading substrates, coupled with the loadlock chamber 108. The transfer chamber 106 comprises a robot assembly 130 operable to pick up and transfer substrates between the loadlock chamber 108, the batch loadlock chamber 109, the MOCVD chamber 102 and the HVPE chamber 104. The movement of the robot assembly 130 may be controlled by a motor drive system (not shown), which may include a servo or stepper motor.

Each processing chamber comprises a chamber body (such as element 112 for the MOCVD chamber 102 and element 114 for the HVPE chamber 104) forming a processing region where a substrate is placed to undergo processing, a chemical delivery module (such as element 116 for the MOCVD chamber 102 and element 118 for the HVPE chamber 104) from which gas precursors are delivered to the chamber body, and an electrical module (such as element 120 for the MOCVD chamber 102 and element 122 for the HVPE chamber 104) that includes the electrical system for each processing chamber of the processing system 100. The MOCVD chamber 102 is adapted to perform CVD processes in which metalorganic elements react with metal hydride elements to form thin layers of compound nitride semiconductor materials. The HVPE chamber 104 is adapted to perform HVPE processes in which gaseous metal halides are used to epitaxially grow thick layers of compound nitride semiconductor materials on heated substrates. In alternate embodiments, one or more additional chambers may 170 be coupled with the transfer chamber 106. These additional chambers may include, for example, anneal chambers, clean chambers for cleaning carrier plates, or substrate removal chambers. The structure of the processing system permits substrate transfers to occur in a defined ambient environment, including under vacuum, in the presence of a selected gas, under defined temperature conditions, and the like.

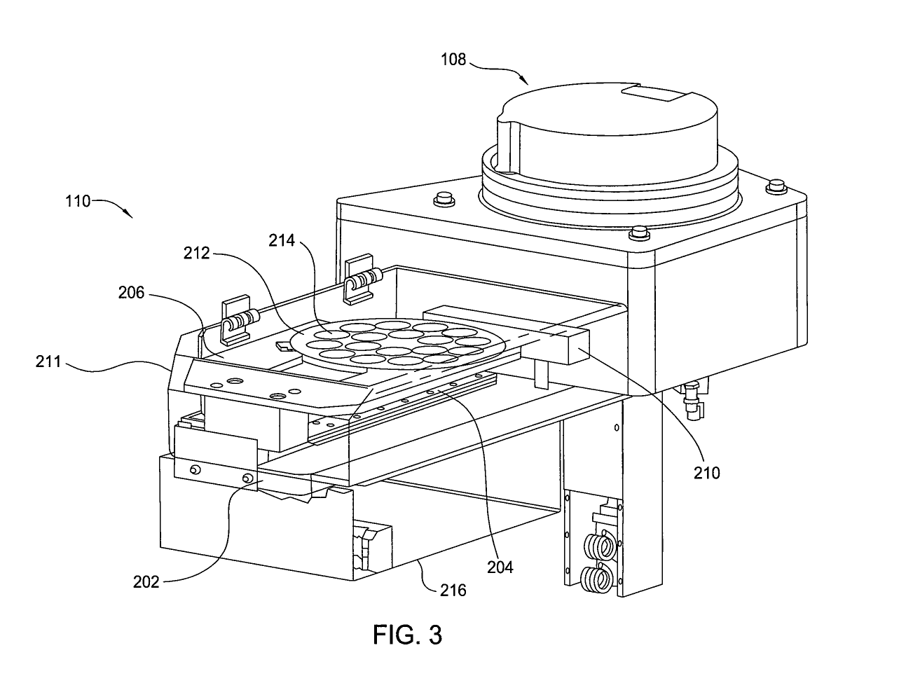

FIG. 3 is an isometric view illustrating a load station 110 and a loadlock chamber 108 according to an embodiment of the invention. The load station 110 is configured as an atmospheric interface to allow an operator to load a plurality of substrates for processing into the confined environment of the loadlock chamber 108, and unload a plurality of processed substrates from the loadlock chamber 108. The load station 110 comprises a frame 202, a rail track 204, a conveyor tray 206 adapted to slide along the rail track 204 to convey substrates into and out of the loadlock chamber 108 via a slit valve 210, and a lid 211. In one embodiment, the conveyor tray 206 may be moved along the rail track 204 manually by the operator. In another embodiment, the conveyor tray 206 may be driven mechanically by a motor. In yet another embodiment, the conveyor tray 206 is moved along the rail track 204 by a pneumatic actuator.

Substrates for processing may be grouped in batches and transported on the conveyor tray 206. For example, each batch of substrates 214 may be transported on a carrier plate 212 that can be placed on the conveyor tray 206. The lid 211 may be selectively opened and closed over the conveyor tray 206 for safety protection when the conveyor tray 206 is driven in movement. In operation, an operator opens the lid 211 to load the carrier plate 212 containing a batch of substrates on the conveyor tray 206. A storage shelf 216 may be provided for storing carrier plates containing substrates to be loaded. The lid 211 is closed, and the conveyor tray 206 is moved through the slit valve 210 into the loadlock chamber 108. The lid 211 may comprise a glass material, such as Plexiglas or a plastic material to facilitate monitoring of operations of the conveyor tray 206.

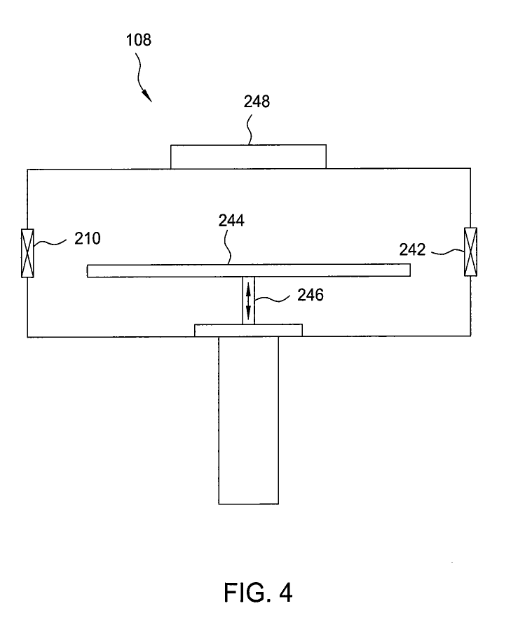

FIG. 4 is a schematic view of a loadlock chamber 108 according to an embodiment of the invention. The loadlock chamber 108 provides an interface between the atmospheric environment of the load station 110 and the controlled environment of the transfer chamber 106. Substrates are transferred between the loadlock chamber 108 and the load station 110 via the slit valve 210 and between the loadlock chamber 108 and the transfer chamber 106 via a slit valve 242. The loadlock chamber 108 comprises a carrier support 244 adapted to support incoming and outgoing carrier plates thereon. In one embodiment, the loadlock chamber 108 may comprise multiple carrier supports that are vertically stacked. To facilitate loading and unloading of a carrier plate, the carrier support 244 may be coupled to a stem 246 vertically movable to adjust the height of the carrier support 244. The loadlock chamber 108 is coupled to a pressure control system (not shown) which pumps down and vents the loadlock chamber 108 to facilitate passing the substrate between the vacuum environment of the transfer chamber 106 and the substantially ambient (e.g., atmospheric) environment of the load station 110. In addition, the loadlock chamber 108 may also comprise features for temperature control, such as a degas module 248 to heat substrates and remove moisture, or a cooling station (not shown) for cooling substrates during transfer. Once a carrier plate loaded with substrates has been conditioned in the loadlock chamber 108, the carrier plate may be transferred into the MOCVD chamber 102 or the HVPE chamber 104 for processing, or to the batch loadlock chamber 109 where multiple carrier plates are stored in standby for processing.

During operation, a carrier plate 212 containing a batch of substrates is loaded on the conveyor tray 206 in the load station 110. The conveyor tray 206 is then moved through the slit valve 210 into the loadlock chamber 108, placing the carrier plate 212 onto the carrier support 244 inside the loadlock chamber 108, and the conveyor tray returns to the load station 110. While the carrier plate 212 is inside the loadlock chamber 108, the loadlock chamber 108 is pumped and purged with an inert gas, such as nitrogen, in order to remove any remaining oxygen, water vapor, and other types of contaminants. After the batch of substrates have been conditioned in the loadlock chamber, the robot assembly 130 may transfer the carrier plate 212 to either the MOCVD chamber 102 or, the HVPE chamber 104 to undergo deposition processes. In alternate embodiments, the carrier plate 212 may be transferred and stored in the batch loadlock chamber 109 on standby for processing in either the MOCVD chamber 102 or the HVPE chamber 104. After processing of the batch of substrates is complete, the carrier plate 212 may be transferred to the loadlock chamber 108, and then retrieved by the conveyor tray 206 and returned to the load station 110.

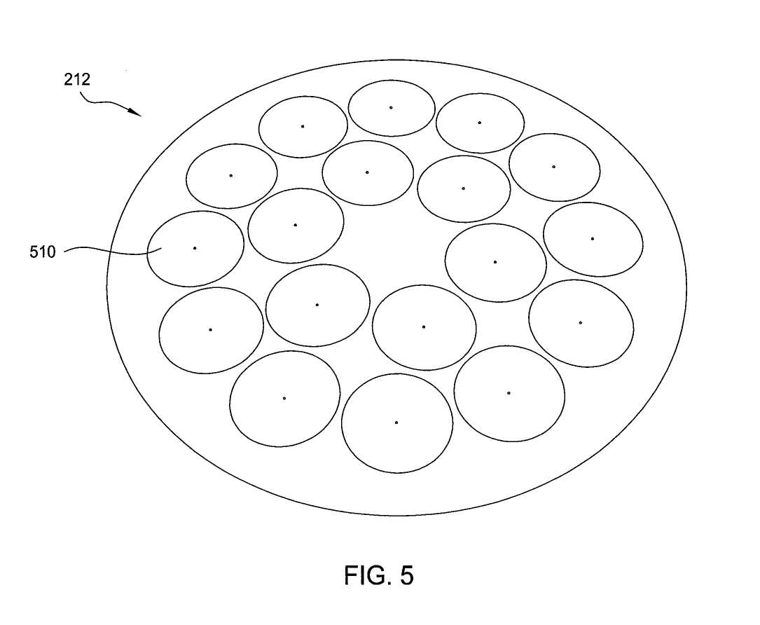

FIG. 5 is an isometric view of a carrier plate according to an embodiment of the invention. In one embodiment, the carrier plate 212 may include one or more circular recesses 510 within which individual substrates may be disposed during processing. The size of each recess 510 may be changed according to the size of the substrate to accommodate therein. In one embodiment, the carrier plate 212 may carry six or more substrates. In another embodiment, the carrier plate 212 carries eight substrates. In yet another embodiment, the carrier plate 212 carries 18 substrates. It is to be understood that more or less substrates may be carried on the carrier plate 212. Typical substrates may include sapphire, silicon carbide (SiC), silicon, or gallium nitride (GaN). It is to be understood that other types of substrates, such as glass substrates, may be processed. Substrate size may range from 50 mm-200 mm in diameter or larger. In one embodiment, each recess 510 may be sized to receive a circular substrate having a diameter between about 2 inches and about 6 inches. The diameter of the carrier plate 212 may range from 200 mm-750 mm, for example, about 300 mm. The carrier plate 212 may be formed from a variety of materials, including SiC, SiC-coated graphite, or other materials resistant to the processing environment. Substrates of other sizes may also be processed within the processing system 100 according to the processes described herein.

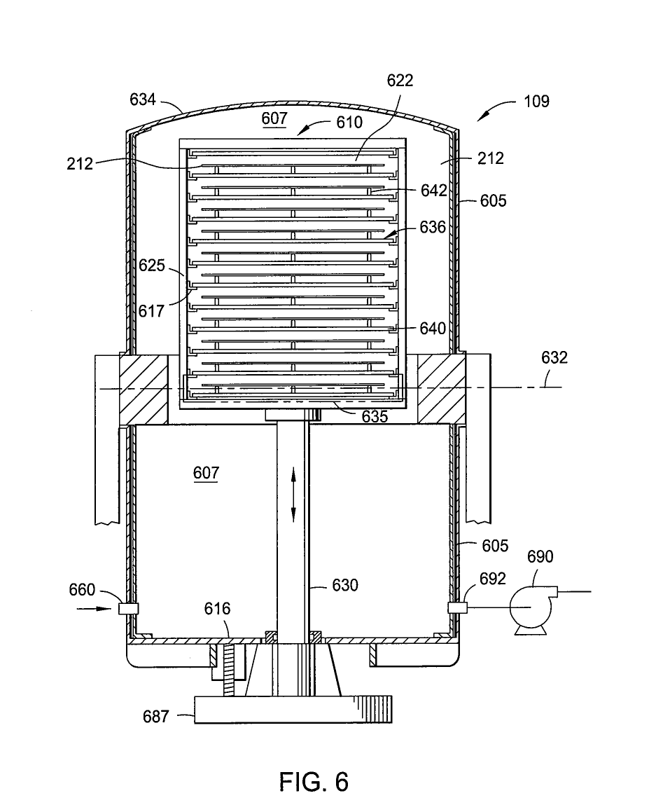

FIG. 6 is a schematic view of the batch loadlock chamber 109 according to an embodiment of the invention. The batch loadlock chamber 109 comprises a body 605 and a lid 634 and bottom 616 disposed on the body 605 and defining a cavity 607 for storing a plurality of substrates placed on the carrier plates 212 therein. In one aspect, the body 605 is formed of process resistant materials such as aluminum, steel, nickel, and the like, adapted to withstand process temperatures and is generally free of contaminates such as copper. The body 605 may comprise a gas inlet 660 extending into the cavity 607 for connecting the batch loadlock chamber 109 to a process gas supply (not shown) for delivery of processing gases therethrough. In another aspect, a vacuum pump 690 may be coupled to the cavity 607 through a vacuum port 692 to maintain a vacuum within the cavity 607.

A storage cassette 610 is moveably disposed within the cavity 607 and is coupled with an upper end of a movable member 630. The moveable member 630 is comprised of process resistant materials such as aluminum, steel, nickel, and the like, adapted to withstand process temperatures and generally free of contaminates such as copper. The movable member 630 enters the cavity 607 through the bottom 616. The movable member 630 is slidably and sealably disposed through the bottom 616 and is raised and lowered by the platform 687. The platform 687 supports a lower end of the movable member 630 such that the movable member 630 is vertically raised or lowered in conjunction with the raising or lowering of the platform 687. The movable member 630 vertically raises and lowers the storage cassette 610 within the cavity 607 to move the substrates carrier plates 212 across a substrate transfer plane 632 extending through a window 635. The substrate transfer plane 632 is defined by the path along which substrates are moved into and out of the storage cassette 610 by the robot assembly 130.

The storage cassette 610 comprises a plurality of storage shelves 636 supported by a frame 625. Although in one aspect, FIG. 6 illustrates twelve storage shelves 636 within storage cassette 610, it is contemplated that any number of shelves may be used. Each storage shelf 636 comprises a substrate support 640 connected by brackets 617 to the frame 625. The brackets 617 connect the edges of the substrate support 640 to the frame 625 and may be attached to both the frame 625 and substrate support 640 using adhesives such as pressure sensitive adhesives, ceramic bonding, glue, and the like, or fasteners such as screws, bolts, clips, and the like that are process resistant and are free of contaminates such as copper. The frame 625 and brackets 617 are comprised of process resistant materials such as ceramics, aluminum, steel, nickel, and the like that are process resistant and are generally free of contaminates such as copper. While the frame 625 and brackets 617 may be separate items, it is contemplated that the brackets 617 may be integral to the frame 625 to form support members for the substrate supports 640.

The storage shelves 636 are spaced vertically apart and parallel within the storage cassette 610 to define a plurality of storage spaces 622. Each substrate storage space 622 is adapted to store at least one carrier plate 212 therein supported on a plurality of support pins 642. The storage shelves 636 above and below each carrier plate 212 establish the upper and lower boundary of the storage space 622.

In another embodiment, substrate support 640 is not present and the carrier plates 212 rest on brackets 617.

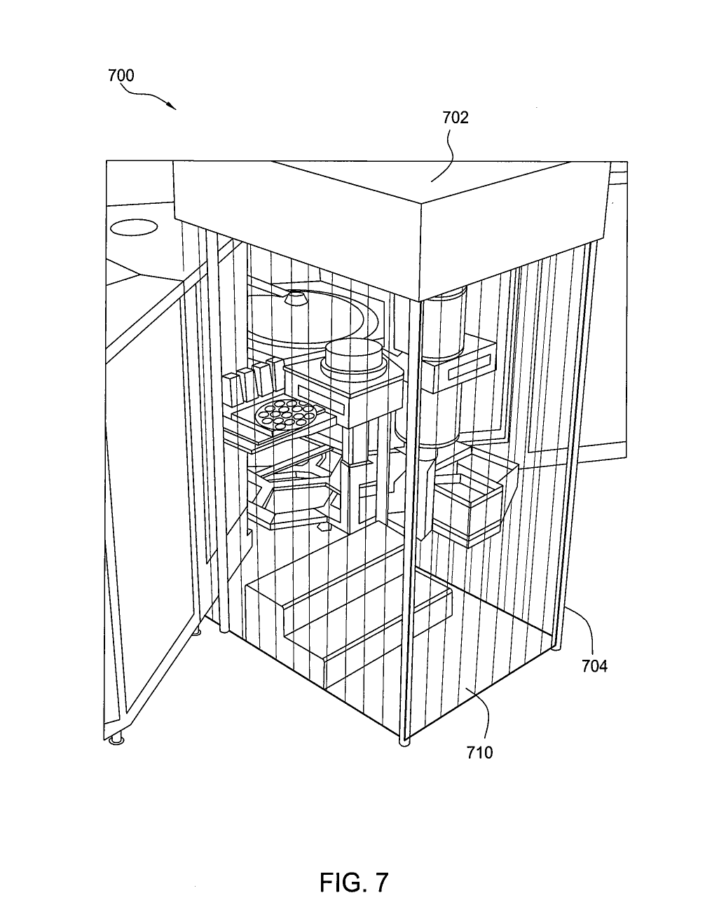

FIG. 7 is an isometric view of a work platform 700 according to one embodiment of the invention. In one embodiment, the processing system 100 further comprises a work platform 700 enclosing the load station 110. The work platform 700 provides a particle free environment during loading and unloading of substrates into the load station 110. The work platform 700 comprises a top portion 702 supported by four posts 704. A curtain 710 separates the environment inside the work platform 700 from the surrounding environment. In one embodiment, the curtain 710 comprises a vinyl material. In one embodiment the work platform comprises an air filter, such as a High Efficiency Particulate Air Filter (“HEPA”) filter for filtering airborne particles from the ambient inside the work platform. In one embodiment, air pressure within the enclosed work platform 700 is maintained at a slightly higher pressure than the atmosphere outside of the work platform 700 thus causing air to flow out of the work platform 700 rather than into the work platform 700.

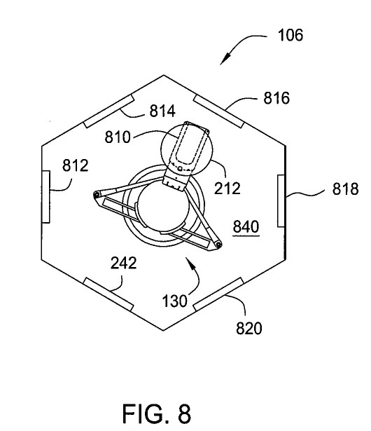

FIG. 8 is a plan view of a robot assembly 130 shown in the context of the transfer chamber 106. The internal region (e.g., transfer region 840) of the transfer chamber 106 is typically maintained at a vacuum condition and provides an intermediate region in which to shuttle substrates from one chamber to another and/or to the load lock chamber 108 and other chambers in communication with the cluster tool. The vacuum condition is typically achieved by use of one or more vacuum pumps (not shown), such as a conventional rough pump, Roots Blower, conventional turbo-pump, conventional cryo-pump, or combination thereof. Alternately, the internal region of the transfer chamber 106 may be an inert environment that is maintained at or near atmospheric pressure by continually delivering an inert gas to the internal region. Three such platforms are the Centura, the Endura and the Producer system all available from Applied Materials, Inc., of Santa Clara, Calif. The details of one such staged-vacuum substrate processing system are disclosed in U.S. Pat. No. 5,186,718, entitled “Staged-Vacuum Substrate Processing System and Method,” Tepman et al., issued on Feb. 16, 1993, which is incorporated herein by reference. The exact arrangement and combination of chambers may be altered for purposes of performing specific steps of a fabrication process.

The robot assembly 130 is centrally located within the transfer chamber 106 such that substrates can be transferred into and out of adjacent processing chambers, the loadlock chamber 108, and the batch loadlock chamber 109, and other chambers through slit valves 242, 812, 814, 816, 818, and 820 respectively. The valves enable communication between the processing chambers, the loadlock chamber 108, the batch loadlock chamber 109, and the transfer chamber 106 while also providing vacuum isolation of the environments within each of the chambers to enable a staged vacuum within the system. The robot assembly 130 may comprise a frog-leg mechanism. In certain embodiments, the robot assembly 130 may comprise any variety of known mechanical mechanisms for effecting linear extension into and out of the various process chambers. A blade 810 is coupled with the robot assembly 130. The blade 810 is configured to transfer the carrier plate 212 through the processing systems. In one embodiment, the processing system 100 comprises an automatic center finder (not shown). The automatic center finder allows for the precise location of the carrier plate 212 on the robot assembly 130 to be determined and provided to a controller. Knowing the exact center of the carrier plate 212 allows the computer to adjust for the variable position of each carrier plate 212 on the blade and precisely position each carrier plate 212 in the processing chambers.

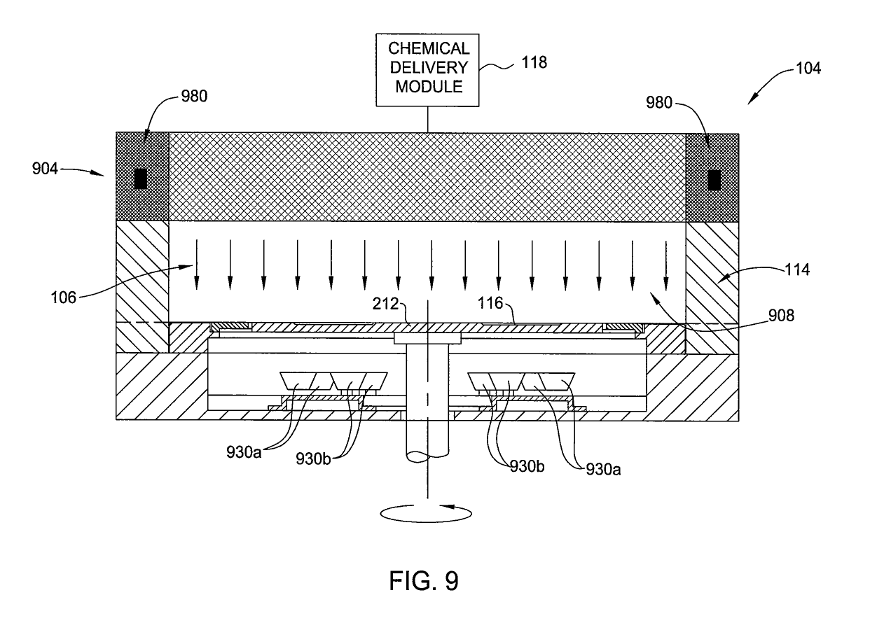

FIG. 9 is a schematic cross-sectional view of a HVPE chamber 104 according to an embodiment of the invention. The HVPE chamber 104 includes the chamber body 114 that encloses a processing volume 908. A showerhead assembly 904 is disposed at one end of the processing volume 908, and the carrier plate 212 is disposed at the other end of the processing volume 908. The showerhead assembly, as described above, may allow for more uniform deposition across a greater number of substrates or larger substrates than in traditional HVPE chambers, thereby reducing production costs. The showerhead may be coupled with a chemical delivery module 118. The carrier plate 212 may rotate about its central axis during processing. In one embodiment, the carrier plate 212 may be rotated at about 2 RPM to about 100 RPM. In another embodiment, the carrier plate 212 may be rotated at about 30 RPM. Rotating the carrier plate 212 aids in providing uniform exposure of the processing gases to each substrate.

A plurality of lamps 930a, 930b may be disposed below the carrier plate 212. For many applications, a typical lamp arrangement may comprise banks of lamps above (not shown) and below (as shown) the substrate. One embodiment may incorporate lamps from the sides. In certain embodiments, the lamps may be arranged in concentric circles. For example, the inner array of lamps 930b may include eight lamps, and the outer array of lamps 930a may include twelve lamps. In one embodiment of the invention, the lamps 930a, 930b are each individually powered. In another embodiment, arrays of lamps 930a, 930b may be positioned above or within showerhead assembly 904. It is understood that other arrangements and other numbers of lamps are possible. The arrays of lamps 930a, 930b may be selectively powered to heat the inner and outer areas of the carrier plate 212. In one embodiment, the lamps 930a, 930b are collectively powered as inner and outer arrays in which the top and bottom arrays are either collectively powered or separately powered. In yet another embodiment, separate lamps or heating elements may be positioned over and/or under the source boat 980. It is to be understood that the invention is not restricted to the use of arrays of lamps. Any suitable heating source may be utilized to ensure that the proper temperature is adequately applied to the processing chamber, substrates therein, and a metal source. For example, it is contemplated that a rapid thermal processing lamp system may be utilized such as is described in United States Patent Publication No. 2006/0018639, published Jan. 26, 2006, entitled PROCESSING MULTILAYER SEMICONDUCTORS WITH MULTIPLE HEAT SOURCES, which is incorporated by reference in its entirety.

In yet another embodiment, the source boat 980 is remotely located with respect to the chamber body 114, as described in U.S. Provisional Patent Application Ser. No. 60/978,040, filed Oct. 5, 2007, titled METHOD FOR DEPOSITING GROUP III/V COMPOUNDS, which is incorporated by reference in its entirety.

One or more lamps 930a, 930b may be powered to heat the substrates as well as the source boat 980. The lamps may heat the substrate to a temperature of about 900 degrees Celsius to about 1200 degrees Celsius. In another embodiment, the lamps 930a, 930b maintain a metal source within the source boat 980 at a temperature of about 350 degrees Celsius to about 900 degrees Celsius. A thermocouple may be used to measure the metal source temperature during processing. The temperature measured by the thermocouple may be fed back to a controller that adjusts the heat provided from the heating lamps 930a, 930b so that the temperature of the metal source may be controlled or adjusted as necessary.

During the process according to one embodiment of the invention, precursor gases 906 flow from the showerhead assembly 904 towards the substrate surface. Reaction of the precursor gases 906 at or near the substrate surface may deposit various metal nitride layers upon the substrate, including GaN, AlN, and InN. Multiple metals may also be utilized for the deposition of “combination films” such as AlGaN and/or InGaN. The processing volume 908 may be maintained at a pressure of about 760 Torr down to about 100 Torr. In one embodiment, the processing volume 908 is maintained at a pressure of about 450 Torr to about 760 Torr. Exemplary embodiments of the showerhead assembly 904 and other aspects of the HVPE chamber are described in U.S. patent application Ser. No. 11/767,520, filed Jun. 24, 2007, entitled HVPE TUBE SHOWERHEAD DESIGN, which is herein incorporated by reference in its entirety.

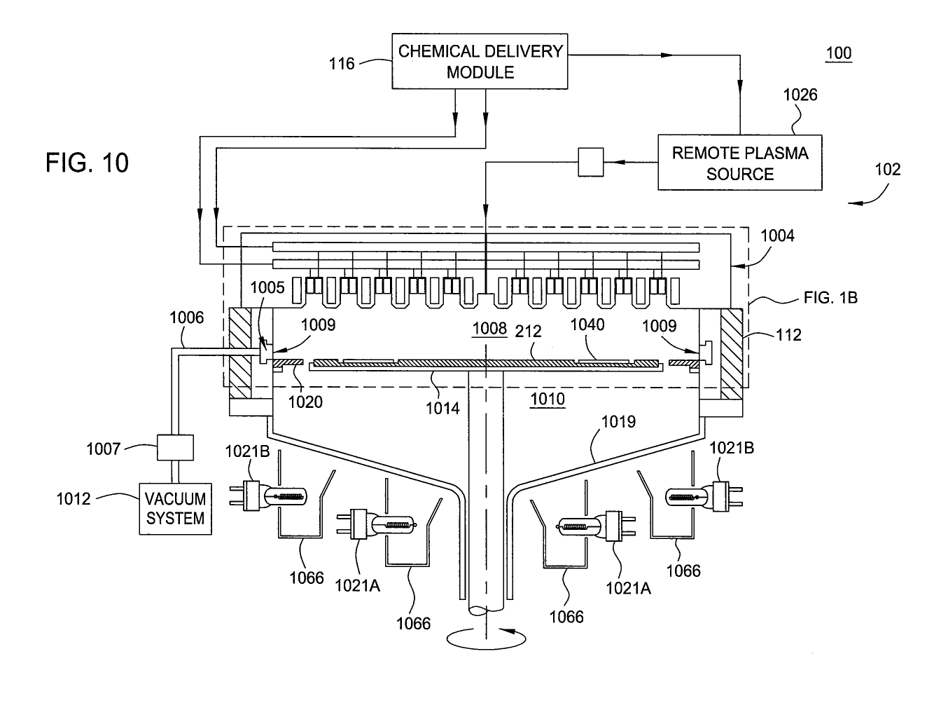

FIG. 10 is a schematic cross-sectional view of an MOCVD chamber according to an embodiment of the invention. The MOCVD chamber 102 comprises a chamber body 112, a chemical delivery module 116, a remote plasma source 1026, a substrate support 1014, and a vacuum system 1012. The chamber 102 includes a chamber body 112 that encloses a processing volume 1008. A showerhead assembly 1004 is disposed at one end of the processing volume 1008, and a carrier plate 212 is disposed at the other end of the processing volume 1008. The carrier plate 212 may be disposed on the substrate support 1014. Exemplary showerheads that may be adapted to practice the present invention are described in U.S. patent application Ser. No. 11/873,132, filed Oct. 16, 2007, entitled MULTI-GAS STRAIGHT CHANNEL SHOWERHEAD, U.S. patent application Ser. No. 11/873,141, filed Oct. 16, 2007, entitled MULTI-GAS SPIRAL CHANNEL SHOWERHEAD, and Ser. No. 11/873,170, filed Oct. 16, 2007, entitled MULTI-GAS CONCENTRIC INJECTION SHOWERHEAD, all of which are incorporated by reference in their entireties.

A lower dome 1019 is disposed at one end of a lower volume 1010, and the carrier plate 212 is disposed at the other end of the lower volume 1010. The carrier plate 212 is shown in process position, but may be moved to a lower position where, for example, the substrates 1040 may be loaded or unloaded. An exhaust ring 1020 may be disposed around the periphery of the carrier plate 212 to help prevent deposition from occurring in the lower volume 1010 and also help direct exhaust gases from the chamber 102 to exhaust ports 1009. The lower dome 1019 may be made of transparent material, such as high-purity quartz, to allow light to pass through for radiant heating of the substrates 140. The radiant heating may be provided by a plurality of inner lamps 1021A and outer lamps 1021B disposed below the lower dome 1019 and reflectors 1066 may be used to help control the chamber 102 exposure to the radiant energy provided by inner and outer lamps 1021A, 1021B. Additional rings of lamps may also be used for finer temperature control of the substrates 1040.

A purge gas (e.g., nitrogen) may be delivered into the chamber 102 from the showerhead assembly 1004 and/or from inlet ports or tubes (not shown) disposed below the carrier plate 212 and near the bottom of the chamber body 112. The purge gas enters the lower volume 1010 of the chamber 102 and flows upwards past the carrier plate 212 and exhaust ring 1020 and into multiple exhaust ports 1009 which are disposed around an annular exhaust channel 1005. An exhaust conduit 1006 connects the annular exhaust channel 1005 to a vacuum system 1012 which includes a vacuum pump (not shown). The chamber 102 pressure may be controlled using a valve system 1007 which controls the rate at which the exhaust gases are drawn from the annular exhaust channel 1005. Other aspects of the MOCVD chamber are described in U.S. patent application Ser. No. ______, filed Jan. 31, 2008, (attorney docket no. 011977) entitled CVD APPARATUS, which is herein incorporated by reference in its entirety.

Various metrology devices, such as, for example, reflectance monitors, thermocouples, or other temperature devices may also be coupled with the chamber 102. The metrology devices may be used to measure various film properties, such as thickness, roughness, composition, temperature or other properties. These measurements may be used in an automated real-time feedback control loop to control process conditions such as deposition rate and the corresponding thickness. Other aspects of chamber metrology are described in U.S. patent application Ser. No. ______, filed Jan. 31, 2008, (attorney docket no. 011007) entitled CLOSED LOOP MOCVD DEPOSITION CONTROL, which is herein incorporated by reference in its entirety.

The chemical delivery modules 116, 118 supply chemicals to the MOCVD chamber 102 and HVPE chamber 104 respectively. Reactive and carrier gases are supplied from the chemical delivery system through supply lines into a gas mixing box where they are mixed together and delivered to respective showerheads 1004 and 904. Generally supply lines for each of the gases include shut-off valves that can be used to automatically or manually shut-off the flow of the gas into its associated line, and mass flow controllers or other types of controllers that measure the flow of gas or liquid through the supply lines. Supply lines for each of the gases may also include concentration monitors for monitoring precursor concentrations and providing real time feedback, backpressure regulators may be included to control precursor gas concentrations, valve switching control may be used for quick and accurate valve switching capability, moisture sensors in the gas lines measure water levels and can provide feedback to the system software which in turn can provide warnings/alerts to operators. The gas lines may also be heated to prevent precursors and etchant gases from condensing in the supply lines. Depending upon the process used some of the sources may be liquid rather than gas. When liquid sources are used, the chemical delivery module includes a liquid injection system or other appropriate mechanism (e.g. a bubbler) to vaporize the liquid. Vapor from the liquids is then usually mixed with a carrier gas as would be understood by a person of skill in the art.

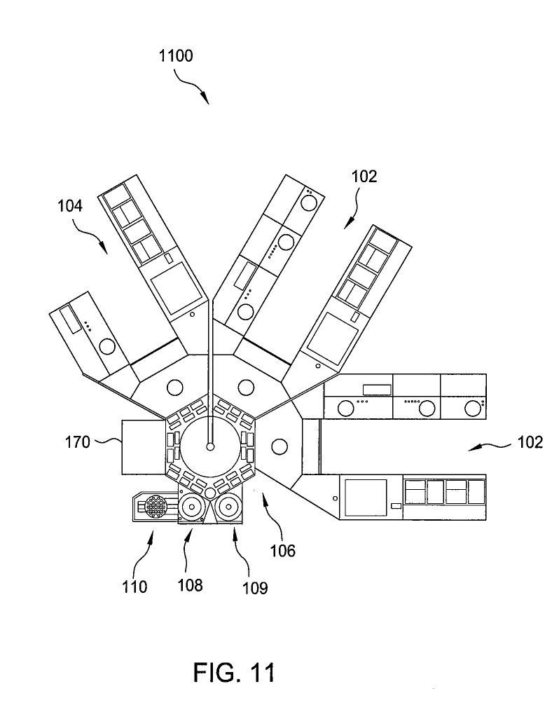

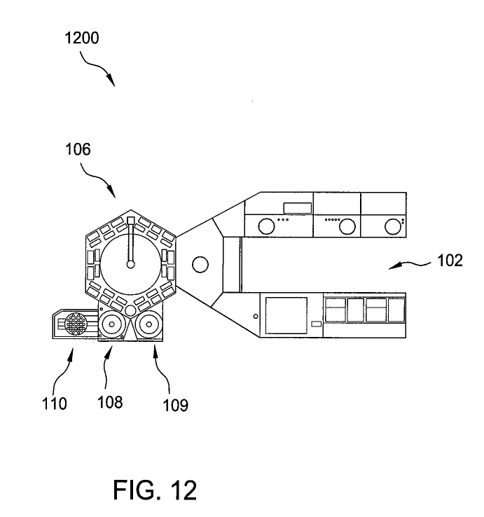

While the foregoing embodiments have been described in connection to a processing system that comprises one MOCVD chamber and one HVPE chamber, alternate embodiments may integrate one or more MOCVD and HVPE chambers in the processing system, as shown in FIGS. 11 and 12. FIG. 11 illustrates an embodiment of a processing system 1100 that comprises two MOCVD chambers 102 and one HVPE chamber 104 coupled to the transfer chamber 106. In the processing system 1100, the robot blade is operable to respectively transfer a carrier plate into each of the MOCVD chambers 102 and HVPE chamber 104. Multiple batches of substrates loaded on separate carrier plates thus can be processed in parallel in each of the MOCVD chambers 102 and HVPE chamber 104.

FIG. 12 illustrates a simpler embodiment of a processing system 1200 that comprises a single MOCVD chamber 102. In the processing system 1200, the robot blade transfers a carrier plate loaded with substrates into the single MOCVD chamber 102 to undergo deposition. After all the deposition steps have been completed, the carrier plate is transferred from the MOCVD chamber 102 back to the loadlock chamber 108, and then released toward the load station 110.

A system controller 160 controls activities and operating parameters of the processing system 100. The system controller 160 includes a computer processor and a computer-readable memory coupled to the processor. The processor executes system control software, such as a computer program stored in memory. Aspects of the processing system and methods of use are further described in U.S. patent application Ser. No. 11/404,516, filed Apr. 14, 2006, entitled EPITAXIAL GROWTH OF COMPOUND NITRIDE STRUCTURES, which is hereby incorporated by reference in its entirety.

The system controller 160 and related control software prioritize tasks and substrate movements based on inputs from the user and various sensors distributed throughout the processing system 100. The system controller 160 and related control software allow for automation of the scheduling/handling functions of the processing system 100 to provide the most efficient use of resources without the need for human intervention. In one aspect, the system controller 160 and related control software adjust the substrate transfer sequence through the processing system 100 based on a calculated optimized throughput or to work around processing chambers that have become inoperable. In another aspect, the scheduling/handling functions pertain to the sequence of processes required for the fabrication of compound nitride structures on substrates, especially for processes that occur in one or more processing chambers. In yet another aspect, the scheduling/handling functions pertain to efficient and automated processing of multiple batches of substrates, whereby a batch of substrates is contained on a carrier. In yet another aspect, the scheduling/handling functions pertain to periodic in-situ cleaning of processing chambers or other maintenance related processes. In yet another aspect, the scheduling/handling functions pertain to temporary storage of substrates in the batch loadlock chamber. In yet another aspect the scheduling/handling functions pertain to transfer of substrates to or from the load station based on operator inputs.

The following example is provided to illustrate how the general process described in connection with processing system 100 may be used for the fabrication of compound nitride structures. The example refers to a LED structure, with its fabrication being performed using a processing system 100 having at least two processing chambers, such as MOCVD chamber 102 and HVPE chamber 104. The cleaning and deposition of the initial GaN layers is performed in the HVPE chamber 104, with growth of the remaining InGaN, AlGaN, and GaN contact layers being performed in the MOCVD system 102.

The process begins with a carrier plate containing multiple substrates being transferred into the HVPE chamber 104. The HVPE chamber 104 is configured to provide rapid deposition of GaN. A pretreatment process and/or buffer layer is grown over the substrate in the HVPE chamber 104 using HVPE precursor gases. This is followed by growth of a thick n-GaN layer, which in this example is performed using HVPE precursor gases. In another embodiment the pretreatment process and/or buffer layer is grown in the MOCVD chamber and the thick n-GaN layer is grown in the HVPE chamber.

After deposition of the n-GaN layer, the substrate is transferred out of the HVPE chamber 104 and into the MOCVD chamber 102, with the transfer taking place in a high-purity N₂ atmosphere via the transfer chamber 106. The MOCVD chamber 102 is adapted to provide highly uniform deposition, perhaps at the expense of overall deposition rate. In the MOCVD chamber 102, the InGaN multi-quantum-well active layer is grown after deposition of a transition GaN layer. This is followed by deposition of the p-AlGaN layer and p-GaN layer. In another embodiment the p-GaN layer is grown in the HVPE chamber.

The completed structure is then transferred out of the MOCVD chamber 102 so that the MOCVD chamber 102 is ready to receive an additional carrier plate containing partially processed substrates from the HVPE chamber 104 or from a different processing chamber. The completed structure may either be transferred to the batch loadlock chamber 109 for storage or may exit the processing system 100 via the loadlock chamber 108 and the load station 110.

Before receiving additional substrates the HVPE chamber and/or MOCVD chamber may be cleaned via an in-situ clean process. The cleaning process may comprise etchant gases which thermally etch deposition from chamber walls and surfaces. In another embodiment, the cleaning process comprises a plasma generated by a remote plasma generator. Exemplary cleaning processes are described in U.S. patent application Ser. No. 11/404,516, filed on Apr. 14, 2006, and U.S. patent application Ser. No. 11/767,520, filed on Jun. 24, 2007, titled HVPE SHOWERHEAD DESIGN, both of which are incorporated by reference in their entireties.

An improved system and method for fabricating compound nitride semiconductor devices has been provided. In conventional manufacturing of compound nitride semiconductor structures, multiple epitaxial deposition steps are performed in a single process reactor, with the substrate not leaving the process reactor until all of the steps have been completed resulting in a long processing time, usually on the order of 4-6 hours. Conventional systems also require that the reactor be manually opened in order to remove and insert additional substrates. After opening the reactor, in many cases, an additional 4 hours of pumping, purging, cleaning, opening, and loading must be performed resulting in a total run time of about 8-10 hours per substrate. The conventional single reactor approach also prevents optimization of the reactor for individual process steps.

The improved system provides for simultaneously processing substrates using a multi-chamber processing system that has an increased system throughput, increased system reliability, and increased substrate to substrate uniformity. The multi-chamber processing system expands the available process window for different compound structures by performing epitaxial growth of different compounds in different processing having structures adapted to enhance those specific procedures. Since the transfer of substrates is automated and performed in a controlled environment, this eliminates the need for opening the reactor and performing a long pumping, purging, cleaning, opening, and loading process.

While the foregoing is directed to embodiments of the present invention, other and further embodiments of the invention may be devised without departing from the basic scope thereof, and the scope thereof is determined by the claims that follow.

1. An integrated processing system for manufacturing compound nitride semiconductor devices, comprising:
one or more walls that form a transfer region;
a robot disposed in the transfer region;
one or more processing chambers operable to form one or more compound nitride semiconductor layers on a substrate that are in transferable communication with the transfer region;
a loadlock chamber in transferable communication with the transfer region, the loadlock chamber having an inlet valve and an outlet valve to receive at least one substrate into a vacuum environment, and
a load station in communication with the loadlock chamber, wherein the load station comprises a conveyor tray movable to convey a carrier plate loaded with one or more substrates into the loadlock chamber.

2. The system of claim 1, wherein the one or more processing chambers comprise a metalorganic chemical vapor deposition (MOCVD) chamber.

3. The system of claim 2, wherein the one or more processing chambers comprise a hydride vapor phase epitaxy (HVPE) chamber.

4. The system of claim 1, wherein the one or more processing chambers comprise a hydride vapor phase epitaxy (HVPE) chamber.

5. The system of claim 1, wherein the load station comprises a rail track along which the conveyor tray is movable.

6. The system of claim 1, wherein the conveyor tray is movable under a manual force exerted by an operator.

7. The system of claim 1, wherein the conveyor tray is driven by a pneumatic actuator.

8. The system of claim 1, further comprising a batch loadlock chamber in transferable communication with the transfer chamber, the batch loadlock chamber configured to store multiple carrier plates.

9. A processing system for manufacturing compound nitride semiconductor devices comprising:
one or more walls that form a transfer region;
a robot disposed in the transfer region;
a first processing chamber that is in communication with the transfer region, wherein the first processing chamber comprises:
a substrate support positioned within a processing volume of the processing chamber;
a showerhead defining a top portion of the processing region; and
a plurality of lamps forming one or more zones located below the processing region and adapted to direct radiant heat toward the substrate support creating one or more radiant heat zones.
a loadlock chamber in transferable communication with the transfer region; and
a load station in communication with the loadlock chamber, wherein the load station comprises a conveyor tray movable to convey a carrier plate loaded with one or more substrates into the loadlock chamber.

10. The system of claim 9, further comprising a hydride vapor phase epitaxy (HVPE) chamber coupled with the transfer chamber.

11. The processing system of claim 9, further comprising a carrier plated positioned on the substrate support, the carrier plate having multiple recesses for receiving multiple substrates.

12. The system of claim 9, wherein the load station comprises a rail track along which the conveyor tray is movable.

13. The system of claim 9, wherein the conveyor tray is movable under a manual force exerted by an operator.

14. The system of claim 9, wherein the conveyor tray is driven by a pneumatic actuator.

15. The system of claim 9, wherein the load station comprises a lid operable to close over the conveyor tray.

16. The system of claim 9, further comprising a batch loadlock chamber coupled with the transfer chamber.

17. An integrated processing system for manufacturing compound nitride semiconductor devices comprising:
one or more walls that form a transfer region;
a robot disposed in the transfer region;
one or more metalorganic chemical vapor deposition (MOCVD) chambers operable to form one or more compound nitride semiconductor layers on a substrate in transferable communication with the transfer region; and
one or more hydride vapor phase epitaxy (HVPE) chambers operable to form one or more compound nitride semiconductor layers on a substrate in transferable communication with the transfer region.

18. The processing system of claim 17, further comprising a loadlock chamber in transferable communication with the transfer region.

19. The processing system of claim 18, further comprising a batch loadlock chamber in communication with the transfer region, the batch loadlock chamber configured to store multiple carrier plates.

20. The processing system of claim 17, further comprising one or more processing chamber selected from the group comprising an anneal chamber, a clean chamber for cleaning carrier plates, or a substrate removal chamber.
